(19) United States
(12) Patent Application Publication
(10) Pub. No.: US 2022/0256655 A1
(43) Pub. Date: Aug. 11, 2022

(54) CERAMIC HEATER

(71) Applicant: NGK INSULATORS, LTD., Nagoya-City (JP)

(72) Inventors: Masaki ISHIKAWA, Handa-City (JP); Yuji AKATSUKA, Handa-City (JP)

(73) Assignee: NGK INSULATORS, LTD., Nagoya-City (JP)

(21) Appl. No.: 17/451,848

(22) Filed: Oct. 22, 2021

(30) Foreign Application Priority Data
Feb. 10, 2021 (JP) 2021-020056

(51) Int. Cl. H05B 3/28; H05B 3/06

(52) U.S. Cl. CPC H05B 3/283; H05B 3/06

(57) ABSTRACT

A ceramic heater includes an inner-peripheral-side resistance heating element embedded in an inner-peripheral-side region of a ceramic base, an outer-peripheral-side resistance heating element embedded in an outer-peripheral-side region of the ceramic base, outer-peripheral-side power supply terminals supplying electric power to the outer-peripheral-side resistance heating element, and jumpers made of metal meshes and connecting the outer-peripheral-side resistance heating element and the outer-peripheral-side power supply terminals. The jumpers are embedded on a jumper embedded plane different from a plane where the inner-peripheral-side resistance heating element is disposed and from a plane where the outer-peripheral-side resistance heating element is disposed. The jumpers are formed of mesh electrodes that are obtained by dividing a metal mesh disk on the jumper embedded plane into multiple parts.

### BACKGROUND OF THE INVENTION

### 1. Field of the Invention

The present invention relates to a ceramic heater.

### 2. Description of the Related Art

There has hitherto been known a ceramic heater in which an inner-peripheral-side resistance heating element and an outer-peripheral-side resistance heating element are present on the same plane in a ceramic base. For example, Patent Literature (PTL) 1 discloses an example of that type of ceramic heater in which one end of the outer-peripheral-side resistance heating element is connected to one of a pair of outer-peripheral-side power supply terminals through a first conductive plane sheet disposed on a different plane in the ceramic base from the heating element plane and three-dimensionally intersecting the inner-peripheral-side resistance heating element, and in which the other end of the outer-peripheral-side resistance heating element is connected to the other of the pair of outer-peripheral-side power supply terminals through a second conductive plane sheet disposed on the different plane in the ceramic base from the heating element plane and three-dimensionally intersecting the inner-peripheral-side resistance heating element.

### CITATION LIST

### Patent Literature

[PTL 1] Japanese Unexamined Patent Application Publication No. 2015-18704

### SUMMARY OF THE INVENTION

However, because the first and second conductive plane sheets are each constituted by a uniform plane sheet, there is a possibility that cracking may occur in the ceramic base during manufacturing and use of the ceramic heater.

The present invention has been made to solve the above-mentioned problem, and a main object of the present invention is to, in a ceramic heater including an inner-peripheral-side resistance heating element and an outer-peripheral-side resistance heating element disposed on the same plane in a ceramic base, prevent the occurrence of cracking in the ceramic base during manufacturing and use of the ceramic heater.

According to the present invention, a ceramic heater includes an inner-peripheral-side resistance heating element embedded in an inner-peripheral-side region of a ceramic base and an outer-peripheral-side resistance heating element embedded in an outer-peripheral-side region of the ceramic base, the ceramic heater includes: outer-peripheral-side power supply terminals disposed in a central region of the ceramic base and supplying electric power to the outer-peripheral-side resistance heating element; and jumpers made of metal meshes and connecting the outer-peripheral-side resistance heating element and the outer-peripheral-side power supply terminals, the jumpers being embedded on a jumper embedded plane different from a plane where the inner-peripheral-side resistance heating element is disposed and from a plane where the outer-peripheral-side resistance heating element is disposed, wherein the jumpers are formed of mesh electrodes that are obtained by dividing a metal mesh disk on the jumper embedded plane into multiple parts.

With the above-described ceramic heater, since the jumpers are made of the metal meshes, the jumpers are easier to expand and contract in conformity with expansion and contraction of the ceramic base than the case in which each jumper is in the form of a uniform metal plane sheet. Furthermore, since ceramic comes into gaps in the meshes forming the jumpers, a thermal expansion coefficient of each jumper becomes closer to that of the ceramic base than the case in which the jumper is in the form of the uniform metal plane sheet. In addition, since the jumpers are formed of mesh electrodes that are obtained by dividing the metal mesh disk on the jumper embedded plane into multiple parts, the jumper embedded plane is almost entirely covered by the mesh electrodes. As a result, even when the ceramic heater is heated and cooled during manufacturing and use of the ceramic heater, cracking is hard to occur in the ceramic base.

In the ceramic heater according to the present invention, the jumpers and the outer-peripheral-side resistance heating element may be connected through metal-made connection members, and each of the connection members may have a shape in which an area of a surface in contact with corresponding one of the jumpers is greater than an area of a surface in contact with the outer-peripheral-side resistance heating element. With those features, even when a manufacturing method for the ceramic heater includes a step of exposing the surface of the connection member embedded in the ceramic base (or a precursor thereof) on an opposite side to the surface connected to the jumper by grinding, the connection member can be prevented from coming off from the ceramic base (or the precursor thereof) in that step. In other words, even when load is applied to the connection member during the above-mentioned grinding, the connection member is hard to come off because a lateral surface of the connection member is caught by the ceramic base (or the precursor thereof) in the surrounding. In this connection, the connection member may be a member formed by stacking metal meshes in multiple stages.

In the ceramic heater according to the present invention, the jumpers and the outer-peripheral-side resistance heating element may be connected through connection members made of metal meshes. With that feature, since the connection members are made of the metal meshes and are easier to expand and contract during the manufacturing and the use of the ceramic heater. Moreover, since the ceramic comes into gaps in the meshes, a thermal expansion coefficient of each connection member becomes closer to that of the ceramic base. As a result, cracking is harder to occur in the ceramic base.

In the ceramic heater according to the present invention, the inner-peripheral-side region may be a circular region concentric to the ceramic base, the outer-peripheral-side region may be an annular region outside the circular region, the outer-peripheral-side resistance heating element may be disposed in each of division regions obtained by dividing the annular region into multiple parts or disposed one in the annular region, and the jumpers may be disposed in pair for each outer-peripheral-side resistance heating element. In this case, the outer-peripheral-side region may be divided in a manner of dividing the annular region into concentric annular regions by concentric circles, dividing the annular region along line segments in a radial direction, or not only dividing the annular region into concentric annular regions by concentric circles, but also dividing the annular region along line segments in the radial direction.

In the ceramic heater according to the present invention, a spacing between the mesh electrodes may be 3 mm or more and 5 mm or less. The condition of the above spacing being 3 mm or more is preferable in that insulation between the adjacent mesh electrodes can be sufficiently ensured. The condition of the above spacing being 5 mm or less is preferable in that a region where the mesh electrodes are not present is reduced and the reduction of such a region is advantageous in preventing the occurrence of cracking.

In the ceramic heater according to the present invention, an outer edge of each of the mesh electrodes may be positioned on an inner side than an outermost edge of the outer-peripheral-side resistance heating element, and each mesh electrode may overlap the outer-peripheral-side resistance heating element by 2 mm or more. With those features, electrical connections between the outer-peripheral-side resistance heating element and the mesh electrode through the connection members can be more easily ensured. When the mesh electrode is formed to overlap the outer-peripheral-side resistance heating element by 3 mm or more, an area of a connection portion therebetween is increased and hence generation of heat in the connection portion can be suppressed.

In the ceramic heater according to the present invention, at least one of the divided mesh electrodes may be a dummy jumper that is not electrically connected to the inner-peripheral-side resistance heating element and the outer-peripheral-side resistance heating element.

### BRIEF DESCRIPTION OF THE DRAWINGS

FIG. 1 is a plan view of a ceramic heater 10.

FIG. 2 is a sectional view taken along A-A in FIG. 1.

FIG. 3 is a sectional view taken along B-B in FIG. 2.

FIG. 4 is a sectional view taken along C-C in FIG. 2.

FIGS. 5A to 5F are explanatory views illustrating a method of manufacturing the ceramic heater 10.

FIG. 6 is an explanatory view illustrating a use state of the ceramic heater 10.

FIG. 7 is a horizontal sectional view of a ceramic heater 110.

FIG. 8 is a horizontal sectional view of a ceramic heater 210.

FIG. 9 is an enlarged view of a connection member 118c.

FIG. 10 is an enlarged view of a connection member 218c.

### DETAILED DESCRIPTION OF THE INVENTION

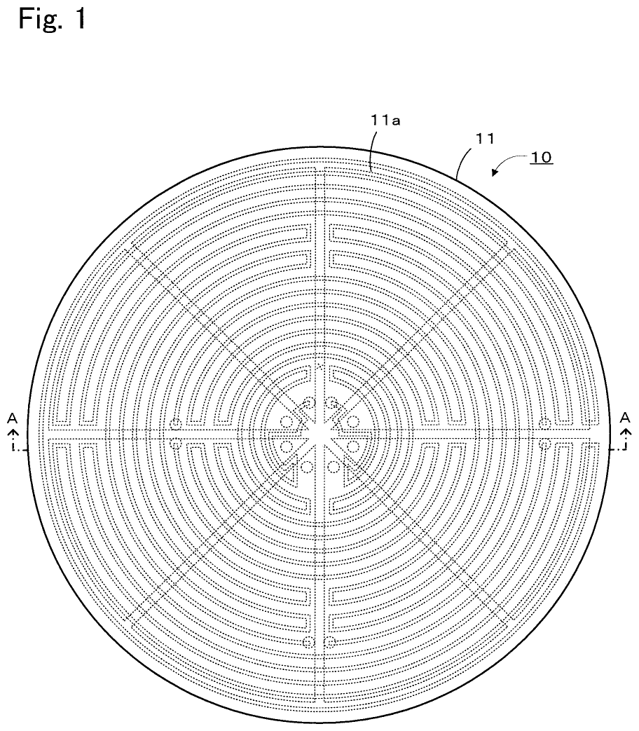

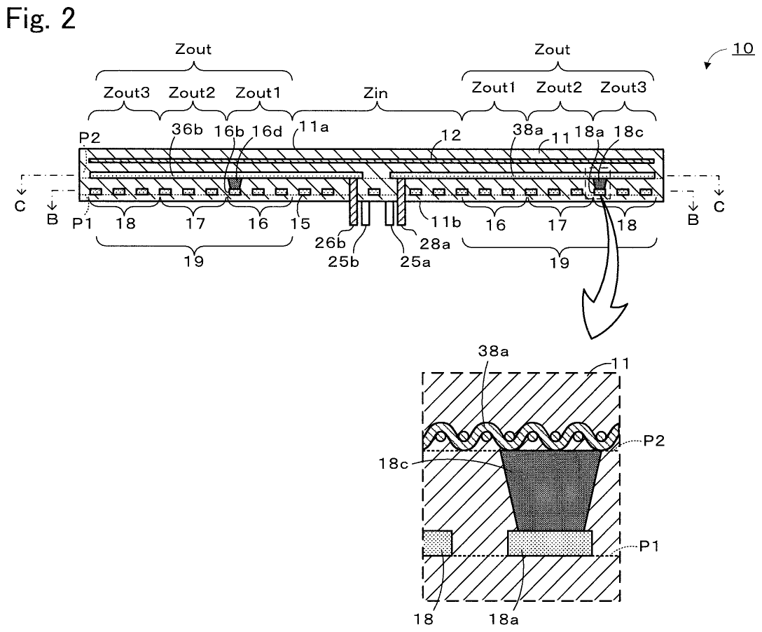

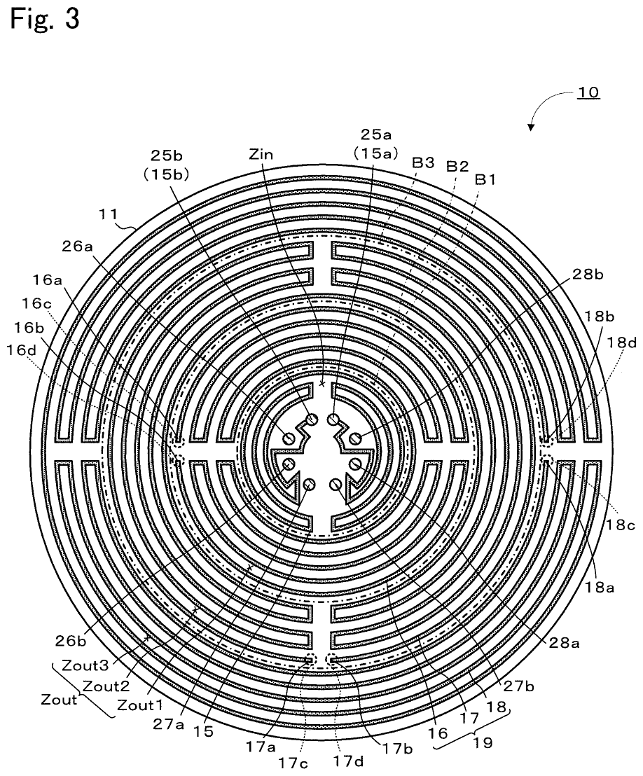

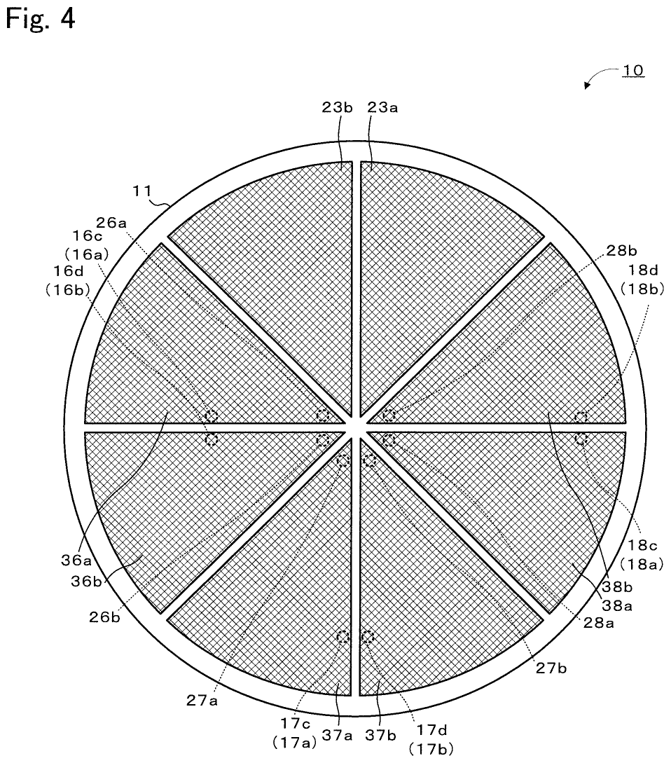

A preferred embodiment of the present invention will be described below with reference to the drawings. FIG. 1 is a plan view of a ceramic heater 10, FIG. 2 is a sectional view taken along A-A in FIG. 1, FIG. 3 is a sectional view taken along B-B in FIG. 2, and FIG. 4 is a sectional view taken along C-C in FIG. 2. In FIGS. 3 and 4, a ceramic base 11 is illustrated without hatching. The words “upper” and “lower” used in this Specification do not represent absolute positional relations but represent relative positional relations. Thus, depending on an orientation of the ceramic heater 10, “upper” and “lower” may change respectively to “lower” and “upper”, “left” and “right”, or “front” and “rear”.

The ceramic heater 10 includes the ceramic base 11, an electrostatic electrode 12, an inner-peripheral-side resistance heating element 15, and an outer-peripheral-side resistance heating element 19.

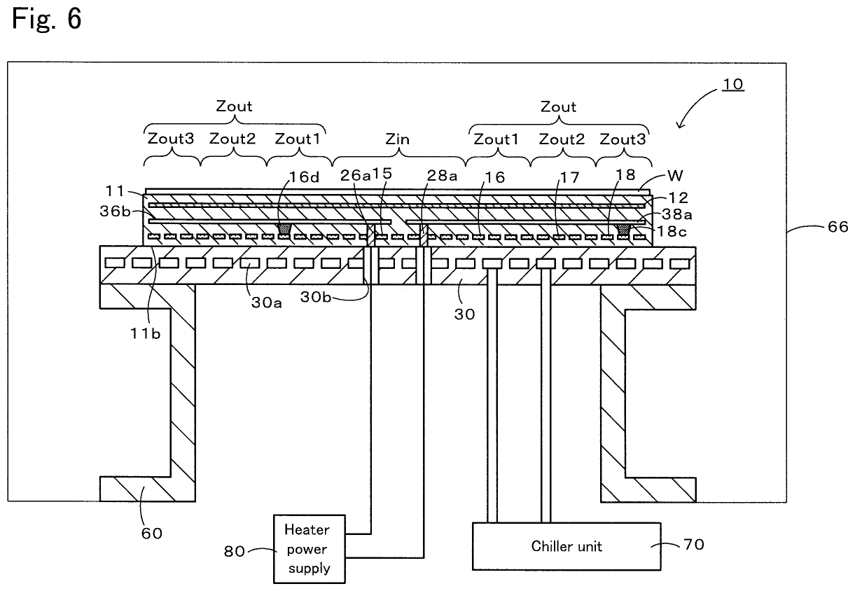

The ceramic base 11 is a disk-shaped member made of a ceramic (for example, an alumina ceramic or an aluminum nitride ceramic). An upper surface of the ceramic base 11 serves as a wafer placement surface 11a on which a wafer W is to be placed. A lower surface of the ceramic base 11 serves as a cooling-plate bonded surface 11b to which a cooling plate 30 (see FIG. 6) is bonded.

The electrostatic electrode 12 is a circular member made of a metal mesh. Power supply terminals (not illustrated) are electrically connected to the electrostatic electrode 12. The power supply terminals extend from a lower surface of the electrostatic electrode 12 through the ceramic base 11 and further extend downward after passing through the cooling plate 30 (see FIG. 6) in an electrically insulated state. A portion of the ceramic base 11, the portion being located closer to the wafer placement surface 11a than the electrostatic electrode 12, functions as a dielectric layer.

The inner-peripheral-side resistance heating element 15 is embedded in an inner-peripheral-side region Zin of the ceramic base 11. Here, the inner-peripheral-side region Zin indicates a circular region inside a first boundary B1 in FIG. 3. The first boundary B1 is a circle concentric to the ceramic base 11 and has a smaller diameter than the ceramic base 11. The inner-peripheral-side resistance heating element 15 is wired in a one-stroke pattern from one end 15a to the other end 15b to extend over the whole of the inner-peripheral-side region Zin. Furthermore, the one end 15a and the other end 15b of the inner-peripheral-side resistance heating element 15 are connected respectively to one inner-peripheral-side power supply terminal 25a and the other inner-peripheral-side power supply terminal 25b. The pair of inner-peripheral-side power supply terminals 25a and 25b are exposed to the outside from the cooling-plate bonded surface 11b of the ceramic base 11. When electric power is supplied to the pair of inner-peripheral-side power supply terminals 25a and 25b, a current flows through the inner-peripheral-side resistance heating element 15, whereby the inner-peripheral-side resistance heating element 15 generates heat.

The outer-peripheral-side resistance heating element 19 is embedded in an outer-peripheral-side region Zout of the ceramic base 11. Here, the outer-peripheral-side region Zout indicates an annular region on an outer side than the first boundary B1 in FIG. 3. More specifically, assuming that an annular region outside the first boundary Bl and inside a second boundary B2 is denoted by a first division region Zout1, that an annular region outside the second boundary B2 and inside a third boundary B3 is denoted by a second division region Zout2, and that an annular region outside the third boundary B3 is denoted by a third division region Zout3, the outer-peripheral-side region Zout is an annular region made up of all the first to third division regions Zout1 to Zout3. The second boundary B2 is a circle concentric to the ceramic base 11 and has a diameter smaller than that of the ceramic base 11 and greater than that of the first boundary B1. The third boundary B3 is a circle concentric to the ceramic base 11 and has a diameter smaller than that of the ceramic base 11 and greater than that of the second boundary B2. The outer-peripheral-side resistance heating element 19 includes a first outer-peripheral-side resistance heating element 16 disposed in the first division region Zout1, a second outer-peripheral-side resistance heating element 17 disposed in the second division region Zout2, and a third outer-peripheral-side resistance heating element 18 disposed in the third division region Zout3. The first outer-peripheral-side resistance heating element 16 is wired in a one-stroke pattern from one end 16a to the other end 16b to extend over the whole of the first division region Zout1 and to position on the same plane P1 as the inner-peripheral-side resistance heating element 15. The second outer-peripheral-side resistance heating element 17 is wired in a one-stroke pattern from one end 17a to the other end 17b to extend over the whole of the second division region Zout2 and to position on the plane P1. The third outer-peripheral-side resistance heating element 18 is wired in a one-stroke pattern from one end 18a to the other end 18b to extend over the whole of the third division region Zout3 and to position on the plane P1.

As illustrated in FIG. 3, the one end 16a and the other end 16b of the first outer-peripheral-side resistance heating element 16 are connected respectively to one connection member 16c and the other connection member 16d, both the connection members extending in a thickness direction of the ceramic base 11. The connection members 16c and 16d are disposed to extend upward from the first outer-peripheral-side resistance heating element 16 relative to the drawing sheet of FIG. 3 and to extend downward from jumpers 36a and 36b, respectively, relative to the drawing sheet of FIG. 4. The other connection member 16d is illustrated in FIG. 2. Furthermore, a pair of first outer-peripheral-side power supply terminals 26a and 26b are disposed in a central zone of the inner-peripheral-side region Zin and have a shape extending in the thickness direction of the ceramic base 11. Lower ends of the first outer-peripheral-side power supply terminals 26a and 26b are exposed to the outside from the cooling-plate bonded surface 11b of the ceramic base 11. The first outer-peripheral-side power supply terminal 26b is illustrated in FIG. 2. One jumper 36a and the other jumper 36b are independently embedded on a jumper embedded plane P2 different from the plane P1 in a three-dimensionally intersecting relation to the inner-peripheral-side resistance heating element 15. The jumper 36b is illustrated in FIG. 2. The jumpers 36a and 36b are each made of a metal mesh of Mo, for example, and have a shape slightly smaller than a fan shape (sector of circle) with the same radius as an outer circumferential circle of the ceramic base 11 and a central angle of 45° in a plan view. The jumper embedded plane P2 is positioned between the plane P1 and the wafer placement surface 11a. Moreover, the one end 16a of the first outer-peripheral-side resistance heating element 16 is connected to the first outer-peripheral-side power supply terminal 26a through the one connection member 16c and the one jumper 36a, and the other end 16b of the first outer-peripheral-side resistance heating element 16 is connected to the first outer-peripheral-side power supply terminal 26b through the other connection member 16d and the other jumper 36b. Therefore, when electric power is supplied to the pair of first outer-peripheral-side power supply terminal 26a and 26b, a current flows through the first outer-peripheral-side resistance heating element 16, whereby the first outer-peripheral-side resistance heating element 16 generates heat.

As illustrated in FIG. 3, the one end 17a and the other end 17b of the second outer-peripheral-side resistance heating element 17 are connected respectively to one connection member 17c and the other connection member 17d, both the connection members extending in the thickness direction of the ceramic base 11. The connection members 17c and 17d are disposed to extend upward from the second outer-peripheral-side resistance heating element 17 relative to the drawing sheet of FIG. 3 and to extend downward from jumpers 37a and 37b, respectively, relative to the drawing sheet of FIG. 4. Furthermore, a pair of second outer-peripheral-side power supply terminals 27a and 27b are disposed in the central zone of the inner-peripheral-side region Zin and have a shape extending in the thickness direction of the ceramic base 11. Lower ends of the second outer-peripheral-side power supply terminals 27a and 27b are exposed to the outside from the cooling-plate bonded surface 11b of the ceramic base 11. One jumper 37a and the other jumper 37b are independently embedded on the jumper embedded plane P2 in a three-dimensionally intersecting relation to the inner-peripheral-side resistance heating element 15. The jumpers 37a and 37b are each made of a metal mesh of Mo, for example, and have the same shape as the jumpers 36a and 36b. Moreover, the one end 17a of the second outer-peripheral-side resistance heating element 17 is connected to the second outer-peripheral-side power supply terminal 27a through the one connection member 17c and the one jumper 37a, and the other end 17b of the second outer-peripheral-side resistance heating element 17 is connected to the second outer-peripheral-side power supply terminal 27b through the other connection member 17d and the other jumper 37b. Therefore, when electric power is supplied to the pair of second outer-peripheral-side power supply terminal 27a and 27b, a current flows through the second outer-peripheral-side resistance heating element 17, whereby the second outer-peripheral-side resistance heating element 17 generates heat.

As illustrated in FIG. 3, the one end 18a and the other end 18b of the third outer-peripheral-side resistance heating element 18 are connected respectively to one connection member 18c and the other connection member 18d, both the connection members extending in the thickness direction of the ceramic base 11. The connection members 18c and 18d are disposed to extend upward from the third outer-peripheral-side resistance heating element 18 relative to the drawing sheet of FIG. 3 and to extend downward from jumpers 38a and 38b, respectively, relative to the drawing sheet of FIG. 4. The one connection member 18c is illustrated in FIG. 2. Furthermore, a pair of third outer-peripheral-side power supply terminals 28a and 28b are disposed in the central zone of the inner-peripheral-side region Zin and have a shape extending in the thickness direction of the ceramic base 11. Lower ends of the third outer-peripheral-side power supply terminals 28a and 28b are exposed to the outside from the cooling-plate bonded surface 11b of the ceramic base 11. The third outer-peripheral-side power supply terminal 28a is illustrated in FIG. 2. One jumper 38a and the other jumper 38b are independently embedded on the jumper embedded plane P2 in a three-dimensionally intersecting relation to the inner-peripheral-side resistance heating element 15. The jumper 38a is illustrated in FIG. 2. The jumpers 38a and 38b are each made of a metal mesh of Mo, for example, and have the same shape as the jumpers 36a and 36b. Moreover, the one end 18a of the third outer-peripheral-side resistance heating element 18 is connected to the third outer-peripheral-side power supply terminal 28a through the one connection member 18c and the one jumper 38a, and the other end 18b of the third outer-peripheral-side resistance heating element 18 is connected to the third outer-peripheral-side power supply terminal 28b through the other connection member 18d and the other jumper 38b. Therefore, when electric power is supplied to the pair of third outer-peripheral-side power supply terminal 28a and 28b, a current flows through the third outer-peripheral-side resistance heating element 18, whereby the third outer-peripheral-side resistance heating element 18 generates heat.

The inner-peripheral-side resistance heating element 15 and the first to third outer-peripheral-side resistance heating elements 16 to 18 are each in the form of a coil, a ribbon, or a mesh and are made of a material containing, as a main component, W, Mo, Ti, Si or Ni singularly or a compound (such as a carbide) of any of those elements, a combined material of two or more of those materials, or a mixed material of any of those materials and a raw material of the ceramic base 11.

The jumpers 36a, 36b, 37a, 37b, 38a, and 38b are formed of mesh electrodes that are obtained by dividing a metal mesh disk covering almost the entirety of the jumper embedded plane P2 into multiple parts. In this embodiment, the metal mesh disk is equally divided into eight fan-shaped mesh electrodes by line segments in a radial direction. A spacing between adjacent two of the mesh electrodes is preferably 3 mm or more and 5 mm or less. Of the eight divided mesh electrodes, the six mesh electrodes serve as the jumpers 36a, 36b, 37a, 37b, 38a, and 38b, and the remaining two are dummy jumpers 23a and 23b. The dummy jumpers 23a and 23b are made of the same material as the other jumpers and are independent electrodes that are not electrically connected to the inner-peripheral-side resistance heating element 15 and the outer-peripheral-side resistance heating element 19. An outer edge of each mesh electrode is preferably positioned a little on an inner side than an outermost edge of the outer-peripheral-side resistance heating element 19 (namely, an outer edge of the third outer-peripheral-side resistance heating element 18). In such a case, each mesh electrode preferably overlaps the third outer-peripheral-side resistance heating element 18 by 2 mm or more.

The connection member 18c illustrated in an enlarged view in FIG. 2 has a shape in which an area of a surface in contact with the jumper 38a is greater than that of a surface in contact with the third outer-peripheral-side resistance heating element 18. The shape of the connection member 18c is preferably such a shape that a cross-sectional area of the connection member 18c when the connection member 18c is cut along a plane parallel to the jumper embedded plane P2 gradually reduces toward the third outer-peripheral-side resistance heating element 18 from the jumper 38a, for example, a truncated conical shape in which a surface on a side closer to the third outer-peripheral-side resistance heating element 18 is smaller than a surface on a side closer to the jumper 38a. The connection member 18c is a bulk body (massive body) made of a mixed material that is obtained, for example, by adding a ruthenium alloy (e.g. RuAl) to tungsten carbide. The connection members 16c, 16d, 17c, 17d, and 18d are also made of the same material and have the same shape as the connection member 18c.

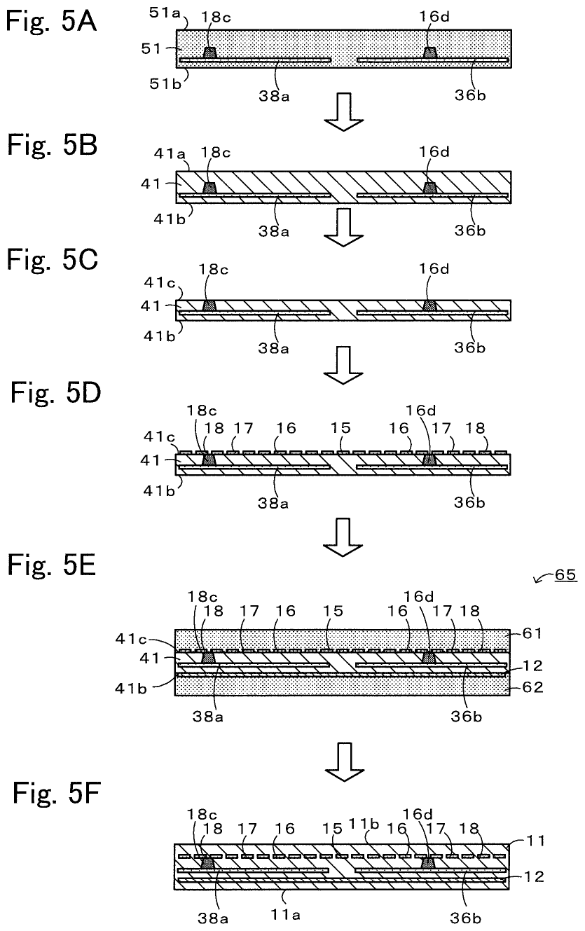

An example of a method of manufacturing the ceramic heater 10 will be described below. FIGS. 5A to 5F are explanatory views illustrating the method of manufacturing the ceramic heater 10. Because FIGS. 5A to 5F are sectional views obtained when the ceramic heater 10 is cut along a similar cut plane to that of FIG. 2, only some of the various members appear.

First, as illustrated in FIG. 5A, a disk-shaped ceramic molded body 51 with two principal surfaces 51a and 51b is fabricated. In the ceramic molded body 51, the jumpers 36a, 36b, 37a, 37b, 38a, and 38b and the dummy jumpers 23a and 23b are embedded on the same plane, and the connection members 16c, 16d, 17c, 17d, 18c, and 18d are further embedded in contact with the jumpers 36a, 36b, 37a, 37b, 38a, and 38b, respectively. The ceramic molded body 51 is fabricated by, for example, a mold casting process. Here, the term “mold casting process” indicates a process of obtaining a molded product by pouring a ceramic slurry, which contains ceramic raw-material powder and a molding agent, into a mold, and by causing the molding agent to develop a chemical reaction in the mold, thus molding the ceramic slurry. The molding agent may be, for example, an agent containing isocyanate and polyol and molding the ceramic slurry by urethane reaction.

Then, as illustrated in FIG. 5B, a disk-shaped ceramic fired body 41 with two principal surfaces 41a and 41b is fabricated by firing the ceramic molded body 51 with a hot press while pressure is applied in a thickness direction. Then, as illustrated in FIG. 5C, the principal surface 41a of the ceramic fired body 41 is ground such that surfaces of the connection members 16c, 16d, 17c, 17d, 18c, and 18d on an opposite side to their surfaces connected to the jumpers 36a, 36b, 37a, 37b, 38a, and 38b, respectively, are exposed. A ground surface 41c of the ceramic fired body 41 is thereby formed. Even when load is applied to the connection members 16c, 16d, 17c, 17d, 18c, and 18d during the above-mentioned grinding, the connection members 16c, 16d, 17c, 17d, 18c, and 18d are hard to come off because lateral surfaces of those connection members are caught by the ceramic fired body 41 (namely, a precursor of the ceramic base 11) in the surrounding.

Then, as illustrated in FIG. 5D, the inner-peripheral-side resistance heating element 15 and the first to third outer-peripheral-side resistance heating elements 16 to 18 are formed on the ground surface 41c of the ceramic fired body 41 by, for example, screen printing.

Then, as illustrated in FIG. 5E, a multilayer body 65 is fabricating by arranging the electrostatic electrode 12 on an upper surface of a ceramic molded body 62, arranging the ceramic fired body 41 on the electrostatic electrode 12 such that a surface of the ceramic fired body 41 on which the resistance heating elements 15 to 18 are positioned to face upward, and by arranging a ceramic molded body 61 on the ceramic fired body 41. The ceramic molded bodies 61 and 62 can be formed by, for example, the mold casting process.

Then, as illustrated in FIG. 5F, the ceramic base 11 is fabricated by firing the multilayer body 65 with a hot press while pressure is applied in the thickness direction. Then, holes are formed in the ceramic base 11 as appropriate and the power supply terminals are attached through the holes, whereby the ceramic heater 10 is obtained.

An example of a use method of the ceramic heater 10 will be described below. FIG. 6 is an explanatory view illustrating a use state of the ceramic heater 10. First, the cooling plate 30 is attached to the ceramic heater 10 on a side including the cooling-plate bonded surface 11b. The cooling-plate bonded surface 11b and the cooling plate 30 may be bonded with an adhesive interposed therebetween or joined with a brazing alloy interposed therebetween. As an alternative, they may be attached to each other with an O-ring (of which outer diameter is slightly smaller than the diameter of the ceramic base 11) interposed therebetween, and heat conducting gas may be filled in an enclosed space inside the O-ring. A coolant path 30a allowing a coolant to pass therethrough is formed inside the cooling plate 30. A chiller unit 70 is connected to the coolant path 30a. The chiller unit 70 is a unit for circulating the coolant through the coolant path 30a. Through-holes 30b are formed in the cooling plate 30 to penetrate therethrough in the thickness direction at positions facing the inner-peripheral-side power supply terminals 25a and 25b and the first to third outer-peripheral-side power supply terminals 26a, 26b, 27a, 27b, 28a, and 28b. The inner-peripheral-side power supply terminals 25a and 25b and the first to third outer-peripheral-side power supply terminals 26a, 26b, 27a, 27b, 28a, and 28b are connected to a heater power supply 80 through those through-holes 30b. The heater power supply 80 can independently supply electric powers to the inner-peripheral-side resistance heating element 15 and the first to third outer-peripheral-side resistance heating elements 16 to 18. Then, a pipe-shaped support 60 is attached to a lower surface of the cooling plate 30. Thereafter, the wafer W is placed on the wafer placement surface 11a of the ceramic heater 10 to which the cooling plate 30 and the support 60 have been attached, and the ceramic heater 10 is placed inside a chamber 66. In such a state, an inner space of the chamber 66 is evacuated to a vacuum. An inner space of the support 60 is communicated with the atmosphere. Then, a voltage is applied between the electrostatic electrode 12 and the wafer W, thus attracting the wafer W toward the ceramic base 11 by an electrostatic force. Then, the electric powers are individually supplied to the inner-peripheral-side resistance heating element 15 and the first to third outer-peripheral-side resistance heating elements 16 to 18 from the heater power supply 80, and the coolant is circulated through the coolant path 30a from the chiller unit 70. Temperature of the wafer W can be maintained at a predetermined temperature because the wafer W is heated by the inner-peripheral-side resistance heating element 15 and the first to third outer-peripheral-side resistance heating elements 16 to 18 while the temperature is adjusted by the cooling plate 30 not to be excessively raised.

With the above-described ceramic heater 10 according to this embodiment, since the jumpers 36a, 36b, 37a, 37b, 38a, and 38b are made of the metal meshes, the jumpers 36a, 36b, 37a, 37b, 38a, and 38b are easier to expand and contract in conformity with expansion and contraction of the ceramic base 11 than the case in which each jumper is in the form of a uniform metal plane sheet. Furthermore, since the ceramic comes into gaps in the meshes forming the jumpers 36a, 36b, 37a, 37b, 38a, and 38b, a thermal expansion coefficient of each jumper becomes closer to that of the ceramic base 11 than the case in which the jumper is in the form of the uniform metal plane sheet. In addition, since the jumpers 36a, 36b, 37a, 37b, 38a, and 38b are formed of the mesh electrodes that are obtained by dividing the metal mesh disk on the jumper embedded plane P2 into multiple parts, the jumper embedded plane P2 is almost entirely covered by the mesh electrodes. As a result, even when the ceramic heater 10 is heated and cooled during the manufacturing and the use of the ceramic heater 10, cracking is hard to occur in the ceramic base 11.

Moreover, as illustrated in FIG. 2, the connection member 16d has such a shape that an area of a surface in contact with the jumper 36b is greater than that of a surface in contact with the other end 16b of the first outer-peripheral-side resistance heating element 16. The connection member 18c has such a shape that the area of the surface in contact with the jumper 38a is greater than that of the surface in contact with the one end 18a of the third outer-peripheral-side resistance heating element 18. Therefore, even in a step of, in the manufacturing method for the ceramic heater 10, exposing the surfaces of the connection members 16d and 18c embedded in the ceramic fired body 41 on the opposite side to their surfaces connected to the jumpers 36b and 38a, respectively, by grinding, the connection members 16d and 18c can be prevented from coming off from the ceramic fired body 41 in that step. In other words, even when load is applied to the connection members 16d and 18c during the above-mentioned grinding, the connection members 16d and 18c are hard to come off because the lateral surfaces of those connection members are caught by the ceramic fired body 41 in the surrounding. This point is similarly applied to the other connection members 16c, 17c, 17d, and 18d.

Since almost the entirety of the jumper embedded plane P2 is substantially covered by the jumpers 36a, 36b, 37a, 37b, 38a, and 38b and the dummy jumpers 23a and 23b, a thermal conductivity is substantially constant over the jumper embedded plane P2 when heat is conducted through the jumper embedded plane P2 in a vertical direction. Hence a soaking property is improved.

The spacing between adjacent two of the mesh electrodes constituting the jumpers 36a, 36b, 37a, 37b, 38a, and 38b is preferably 3 mm or more and 5 mm or less. The condition of the above spacing being 3 mm or more is preferable in that insulation between the adjacent mesh electrodes can be sufficiently ensured. The condition of the above spacing being 5 mm or less is preferable in that a region where the mesh electrodes are not present is reduced and the reduction of such a region is advantageous in preventing the occurrence of cracking.

The mesh electrode constituting each of the jumpers 38a and 38b preferably overlaps the third outer-peripheral-side resistance heating element 18 by 2 mm or more. Under such a condition, electrical connections between the jumpers 38a, 38b and the third outer-peripheral-side resistance heating element 18 through the connection members 18c and 18d can be more easily ensured. When the mesh electrode is formed to overlap the third outer-peripheral-side resistance heating element 18 by 3 mm or more, an area of a connection portion therebetween is increased and hence generation of heat in the connection portion can be suppressed. This point is similarly applied to electrical connections between the jumpers 36a, 36b and the first outer-peripheral-side resistance heating element 16 and electrical connections between the jumpers 37a, 37b and the second outer-peripheral-side resistance heating element 17.

It is a matter of course that the present invention is not limited to the above-described embodiment and can be implemented in various forms insofar as falling within the technical scope of the present invention.

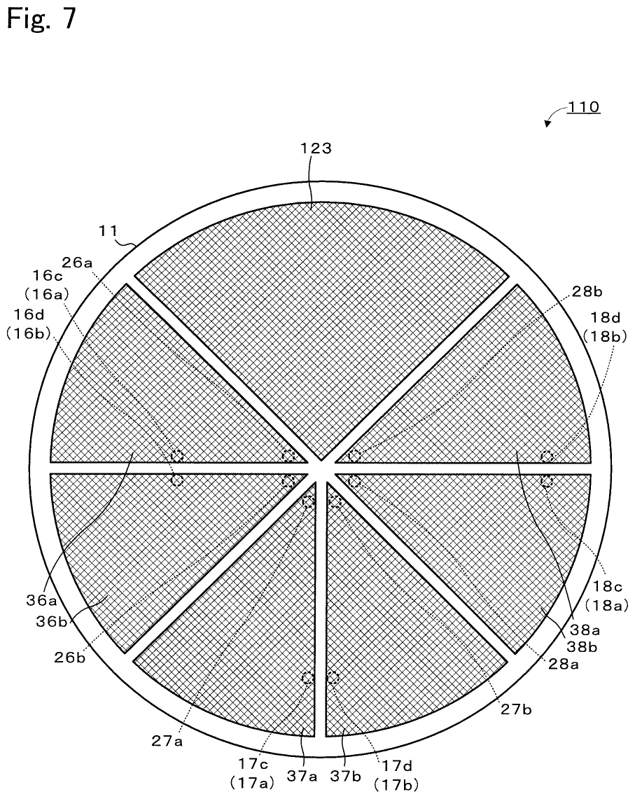

For example, while the above-described embodiment includes the pair of (two) dummy jumpers 23a and 23b (each having the fan shape with the central angle of about 45°), the number of dummy jumpers is not limited to two. Like a ceramic heater 110 illustrated in FIG. 7, for example, one dummy jumper 123 (having a fan shape with the central angle of about 90°) in a plan view may be disposed. The dummy jumper 123 has the fan shape obtained by combining the dummy jumpers 23a and 23b together with omission of the spacing therebetween. Alternatively, the dummy jumper 123 may be divided into three or more parts. FIG. 7 is a sectional view looking at a cross-section from above when a ceramic base 11 of the ceramic heater 110 is cut along a horizontal plane passing the jumpers 36a, 36b, and so on. The same constituent elements in FIG. 7 as those in the above-described embodiment are denoted by the same reference signs and description of those constituent elements is omitted.

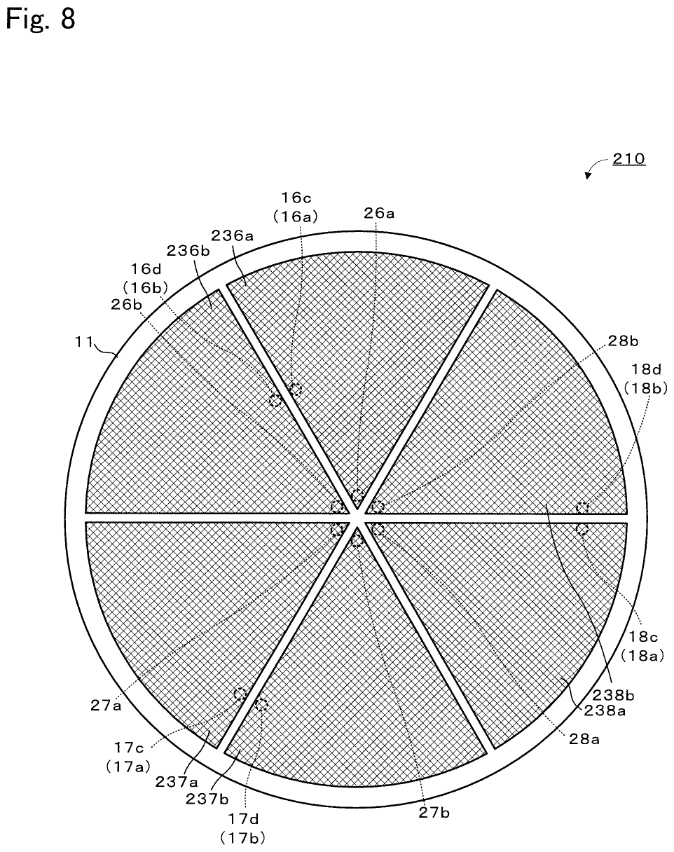

While, in the above-described embodiment, the dummy jumpers 23a and 23b are disposed on the jumper embedded plane P2, the dummy jumpers may not need to be disposed in another example like a ceramic heater 210 illustrated in FIG. 8. FIG. 8 is a sectional view looking at a cross-section from above when a ceramic base 11 of the ceramic heater 210 is cut along a horizontal plane passing jumpers 236a, 236b, and so on. The same constituent elements in FIG. 8 as those in the above-described embodiment are denoted by the same reference signs and description of those constituent elements is omitted. In such a modification, each jumper 236a, 236b, 237a, 237b, 238a, or 238b is one of mesh electrodes that are obtained by dividing the metal mesh disk covering almost the entirety of the jumper embedded plane P2 into parts in the total number (6 here) of jumpers.

While, in the above-described embodiment, the outer-peripheral-side region Zout is divided into the first to third division regions Zout1 to Zout3, the present invention is not limited to that case. For example, the outer-peripheral-side region Zout may be divided into two division regions or four or more division regions. In any of those cases, it is just required to dispose the outer-peripheral-side resistance heating element for each of the division regions and to dispose one set of jumpers corresponding to each outer-peripheral-side resistance heating element. As an alternative, the outer-peripheral-side region Zout may not need to be divided. In such a case, it is just required to dispose one outer-peripheral-side resistance heating element in the outer-peripheral-side region Zout and to dispose one set of jumpers corresponding to the outer-peripheral-side resistance heating element.

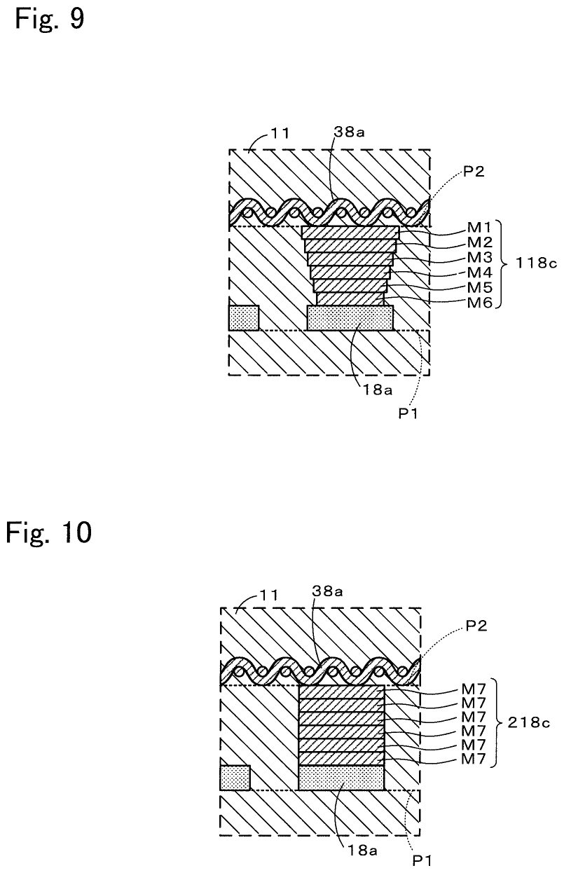

While, in the above-described embodiment, the bulk body (massive body) is used as each of the connection members 16c, 16d, 17c, 17d, 18c, and 18d, the present invention is not limited to that case. For example, as illustrated in FIG. 9, a connection member 118c formed by stacking a plurality (6 here) of metal meshes M1 to M6 with different diameters from one another in descending order of diameter from a side closer to the jumper embedded plane P2 may be used instead of the connection member 18c. The same constituent elements in FIG. 9 as those in the above-described embodiment are denoted by the same reference signs and description of those constituent elements is omitted. The other connection members 16c, 16d, 17c, 17d, and 18d may also have the same structure as the connection member 118c. Alternatively, as illustrated in FIG. 10, a connection member 218c formed by stacking circular metal meshes M7 with equal diameters in multiple stages (6 stages here) may be used instead. The same constituent elements in FIG. 10 as those in the above-described embodiment are denoted by the same reference signs and description of those constituent elements is omitted. The other connection members 16c, 16d, 17c, 17d, and 18d may also have the same structure as the connection member 218c. With use of the connection member 118c or 218c, since the connection member 118c or 218c is made of the metal mesh, the connection member is easier to expand and contract during the manufacturing and the use of the ceramic heater. Furthermore, since the ceramic comes into gaps in the mesh, a thermal expansion coefficient of the connection member becomes closer to that of the ceramic base 11. Moreover, when a peripheral surface of the connection member 118c or 218c is made jagged with the mesh, the connection member 118c or 218c can serve as an anchor for the ceramic base 11.

In the above-described embodiment, an RF electrode may be embedded in the ceramic base 11 in addition to the electrostatic electrode 12, the inner-peripheral-side resistance heating element 15, and the outer-peripheral-side resistance heating element 19. The RF electrode is an electrode used to generate plasma. As an alternative, the electrostatic electrode 12 may not need to be embedded.

While, in the above-described embodiment, the inner-peripheral-side resistance heating element 15 and the first to third outer-peripheral-side resistance heating elements 16 to 18 are embedded on the same plane P1, the present invention is not limited to that case. For example, the inner-peripheral-side resistance heating element 15 and the first to third outer-peripheral-side resistance heating elements 16 to 18 may be embedded on different planes.

While, in the above-described embodiment, the jumpers 36a, 36b, 37a, 37b, 38a, and 38b are formed of the mesh electrodes that are obtained by dividing the metal mesh disk covering almost the entirety of the jumper embedded plane P2 into equal parts, the present invention is not particularly limited to that case. For example, the jumpers 36a, 36b, 37a, 37b, 38a, and 38b may be formed of mesh electrodes that are obtained by dividing the metal mesh disk into unequal parts.

The present application claims priority from Japanese Patent Application No. 2021-20056 filed Feb. 10, 2021, the entire contents of which are incorporated herein by reference.

What is claimed is:

1. A ceramic heater including an inner-peripheral-side resistance heating element embedded in an inner-peripheral-side region of a ceramic base and an outer-peripheral-side resistance heating element embedded in an outer-peripheral-side region of the ceramic base, the ceramic heater comprising:
outer-peripheral-side power supply terminals disposed in a central region of the ceramic base and supplying electric power to the outer-peripheral-side resistance heating element; and
jumpers made of metal meshes and connecting the outer-peripheral-side resistance heating element and the outer-peripheral-side power supply terminals, the jumpers being embedded on a jumper embedded plane different from a plane where the inner-peripheral-side resistance heating element is disposed and from a plane where the outer-peripheral-side resistance heating element is disposed,
wherein the jumpers are formed of mesh electrodes that are obtained by dividing a metal mesh disk on the jumper embedded plane into multiple parts.

2. The ceramic heater according to claim 1, wherein the jumpers and the outer-peripheral-side resistance heating element are connected through metal-made connection members, and each of the connection members has a shape in which an area of a surface in contact with corresponding one of the jumpers is greater than an area of a surface in contact with the outer-peripheral-side resistance heating element.

3. The ceramic heater according to claim 1, wherein the jumpers and the outer-peripheral-side resistance heating element are connected through connection members made of metal meshes.

4. The ceramic heater according to claim 1, wherein the inner-peripheral-side region is a circular region concentric to the ceramic base,
the outer-peripheral-side region is an annular region outside the circular region,
the outer-peripheral-side resistance heating element is disposed in each of division regions obtained by dividing the annular region into multiple parts or disposed one in the annular region, and
the jumpers are disposed in pair for each outer-peripheral-side resistance heating element.

5. The ceramic heater according to claim 1, wherein a spacing between the mesh electrodes is 3 mm or more and 5 mm or less.

6. The ceramic heater according to claim 1, wherein an outer edge of each of the mesh electrodes is positioned on an inner side than an outermost edge of the outer-peripheral-side resistance heating element, and each mesh electrode overlaps the outer-peripheral-side resistance heating element by 2 mm or more.

7. The ceramic heater according to claim 1, wherein at least one of the divided mesh electrodes is a dummy jumper that is not electrically connected to the inner-peripheral-side resistance heating element and the outer-peripheral-side resistance heating element.
